(19) United States
(12) Patent Application Publication
(10) Pub. No.: US 2020/0312973 A1
(43) Pub. Date: Oct. 1, 2020

(54) DUAL TRANSISTOR GATE WORKFUNCTIONS AND RELATED APPARATUSES, SYSTEMS, AND METHODS

(71) Applicant: Intel Corporation, Santa clara, CA (US)

(72) Inventors: Sean T. MA, Portland, OR (US); Abhishek SHARMA, Hillsboro, OR (US); Gilbert DEWEY, Hillsboro, OR (US); Van H. LE, Beaverton, OR (US); Jack T. KAVALIEROS, Portland, OR (US); Tahir GHANI, Portland, OR (US); Benjamin CHU-KUNG, Hillsboro, OR (US); Shriram SHIVARAMAN, Hillsboro, OR (US)

(21) Appl. No.: 16/651,955

(22) PCT Filed: Dec. 21, 2017
(86) PCT No.: PCT/US2017/067928

§ 371 Date: Mar. 27, 2020

(51) Int. Cl. H01L 29/49; H01L 29/66; H01L 29/786

(52) U.S. Cl. CPC H01L 29/4908; H01L 29/7869; H01L 29/78642; H01L 29/66969

(57) ABSTRACT

This disclosure illustrates a transistor with dual gate workfunctions. The transistor with dual gate workfunctions may comprise a source region, a drain region, a channel between the source region and the drain region, and a gate to control a conductivity of the channel. The gate may comprise a first portion with a first workfunction and a second portion with a second workfunction. One of the portions is nearer the source region than the other portion. The workfunction of the portion nearer the source provides a lower thermionic barrier than the workfunction of the portion further away from the source.

### TECHNICAL FIELD

This disclosure generally relates to transistors. Specifically, this disclosure relates to transistors with dual workfunctions in the gate.

### BACKGROUND

Transistors are used in a variety of electrical applications. For example, transistors are often used as an electrically controlled switch. As transistors are scaled to be smaller as the demand for high-density devices increases, performance of these scaled transistors tends to deviate from ideal models known in the art. This trend affects operation and performance of these transistors. For example, thin film transistors may suffer from low drive current due to insufficient injection current.

### BRIEF DESCRIPTION OF THE DRAWINGS

FIG. 1A illustrates a simplified planar view of an n-type Metal Oxide Semiconductor (NMOS) transistor with dual gate workfunctions, according to some embodiments.

FIG. 1B illustrates a simplified planar view of a p-type Metal Oxide Semiconductor (PMOS) transistor with dual gate workfunctions, according to some embodiments.

FIG. 2A illustrates a simplified cross-sectional view taken through the gate of the NMOS transistor of FIG. 1A with dual gate workfunctions.

FIG. 2B illustrates a simplified cross-sectional view taken through the gate of the PMOS transistor of FIG. 1B with dual gate workfunctions.

FIG. 3A illustrates a simplified cross-sectional view taken through the gate of a vertical thin film NMOS transistor with dual gate workfunctions, according to some embodiments.

FIG. 3B illustrates a simplified cross-sectional view taken through the gate of a vertical thin film PMOS transistor with dual gate workfunctions, according to some embodiments.

FIG. 4A illustrates a simplified cross-sectional of a vertical double gate NMOS transistor with dual gate workfunctions, according to some embodiments.

FIG. 4B illustrates a simplified cross-sectional of a vertical double gate PMOS transistor with dual gate workfunctions, according to some embodiments.

FIG. 5 is a simplified flow diagram illustrating a method for fabricating a transistor with dual gate workfunctions, according to some embodiments.

FIG. 6 illustrates a simplified cross-sectional view taken through the gate of a transistor with dual gate workfunctions during various processing stages according to some embodiments.

FIG. 7 illustrates a simplified cross-sectional view taken through the gate of a transistor with dual gate workfunctions during various processing stages according to some embodiments.

FIG. 8 is a graph comparing on-state current of a transistor with dual gate workfunctions with a transistor with a single gate workfunction.

FIG. 9 is a simplified comparing off-state conduction band energy of a transistor with dual gate workfunctions with a transistor with a single gate workfunction.

FIG. 10 is a simplified graph comparing on-state conduction band energy of a transistor with dual gate workfunctions with a transistor with a single gate workfunction.

FIG. 11 is an interposer implementing one or more embodiments of the disclosure.

FIG. 12 is a computing device built in accordance with an embodiment of the disclosure.

### DETAILED DESCRIPTION OF PREFERRED EMBODIMENTS

Described herein are transistors with dual gate workfunctions and related systems and methods. The dual gate workfunctions may increase drive current over a conventional single gate workfunction transistor, and maintain an off-state barrier similar to a conventional single gate workfunction transistor. In the following description, various aspects of the illustrative implementations will be described using terms commonly employed by those skilled in the art to convey the substance of their work to others skilled in the art. However, it will be apparent to those skilled in the art that the disclosure may be practiced with only some of the described aspects. For purposes of explanation, specific numbers, materials and configurations are set forth in order to provide a thorough understanding of the illustrative implementations. However, it will be apparent to one skilled in the art that the disclosure may be practiced without the specific details. In other instances, well-known features are omitted or simplified in order not to obscure the illustrative implementations.

Various operations will be described as multiple discrete operations, in turn, in a manner that is most helpful in understanding the disclosure. The order of the description, however, should not be construed to imply that these operations are necessarily order dependent. In particular, these operations need not be performed in the order of presentation.

The terms “over,” “under,” “between,” and “on,” as used herein, refer to a relative position of one material (e.g., region, structure, layer, etc.) or component with respect to other materials (e.g., regions, structures, layers, etc.) or components. For example, one material disposed over, under, between or on another material may be directly in contact with the other material or may have one or more intervening materials. Similarly, unless explicitly stated otherwise, one feature disposed between two features may be in direct contact with the adjacent features or may have one or more intervening layers.

Implementations of the disclosure may be formed or carried out on a substrate, such as a semiconductor substrate. In one implementation, the semiconductor substrate may be a crystalline substrate formed using a bulk silicon or a silicon-on-insulator (SOI) substructure. In other implementations, the semiconductor substrate may be formed using alternative materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode is formed on the gate dielectric and may consist of at least one p-type workfunction metal or n-type workfunction metal, depending on whether the transistor is to be a PMOS or an NMOS transistor. In some implementations, the gate electrode may consist of a stack of two or more metals, where one or more metals are workfunction metals and at least one metal is a fill metal. Additional metals may be included for other purposes, such as a barrier material.

For a PMOS transistor, metals that may be used for the gate electrode include, but are not limited to, ruthenium, palladium, platinum, cobalt, nickel, and conductive metal oxides, e.g., ruthenium oxide. A p-type metal layer will enable the formation of a PMOS gate electrode with a workfunction that is between about 4.6 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An n-type metal will enable the formation of an NMOS gate electrode with a workfunction that is between about 3.9 eV and about 4.5 eV.

In some implementations, when viewed as a cross section of the transistor along the source-channel-drain direction, the gate electrode may consist of a U-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may include a combination of U-shaped structures and planar, non-U-shaped structures. For example, the gate electrode may consist of one or more U-shaped metals formed atop one or more planar, non-U-shaped materials.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternative implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternative semiconductor materials such as germanium or a group III-V material or alloy. In further embodiments, one or more metals and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

Drive current, injection current, and leakage current of transistors is a concern for integrated circuit design. Drive current is at a drain of a transistor when the transistor is in an on-state. Drive current limits what components can be controlled by a transistor. As some new technologies require more power, it is desirable for drive current to be increased. For example, a high drive current may be needed for transistors controlling pixels of a 4K display. Injection current is the current between a source and a drain of a transistor during an on-state.

One way to increase the drive current is to simply reduce the threshold voltage of a transistor. However, lowering the threshold voltage will also affect the leakage current. Leakage current is the current between a source and a drain of a transistor when the transistor is in an off-state. A lower leakage current is desirable to increase efficiency of the transistor. Typically, lowering the threshold voltage will increase drive current and leakage current. Thus, using this method, a transistor design sacrifices efficiency to improve drive current.

However, this solution is not desirable for mobile devices as battery life would be decreased. As mobile devices become increasingly complex and components of the devices require more power, it is desirable to develop transistors that can limit leakage current and increase drive current.

Described herein are transistors that use gates with multiple workfunctions to control a the injection current without the inefficiencies of excessively low leakage current. The transistors with multiple workfunctions may be configured to have a leakage current similar to a transistor with a single workfunction due to a similar off-state thermionic barrier. Additionally, the transistors with multiple workfunctions may have an increased drive current when compared to a transistor with a single workfunction due to a lower source thermionic barrier during on-state.

Drive current is particularly limited with thin film transistors. Thin film transistors typically suffer from low drive current. This is at least partially due to low carrier mobility of a thin film transistor. This makes thin film transistors good for power conservation during an off state, but difficult to change to an on state. Materials used for thin film transistor channels often have high resistivity that limits the carrier mobility. For example, some channels comprise non-silicon material such as metal oxide or transparent metal. Because of the low drive current thin film transistors have conventionally been limited to displays. However, a thin film transistor with a multi-workfunction gate may be configured to be used as a standard transistor. A multi-workfunction gate as described herein can be applied to a thin film transistor to increase the drive current by reducing the thermionic barrier during an on state. Further, the off state thermionic barrier may be preserved.

The embodiments described below with reference to the drawings include thin film transistors. While a multi-workfunction gate can be used to improve drive current of a thin film transistor, other transistor architectures and geometries may incorporate a multi-workfunction gate to improve drive current. For example, a single gate transistor with a gate along the bottom or top may use a multi-workfunction gate. A vertical transistor or a double gate transistor can also use a multi-workfunction gate. Other transistor architectures and geometries that can use a multi-workfunction gate include, but are not limited to, FinFET transistors, nanowires, and nanoribbons.

Additional details and examples are provided with reference to the figures below. The embodiments of the disclosure can be understood by reference to the drawings, wherein like parts are designated by like numerals throughout. The components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments.

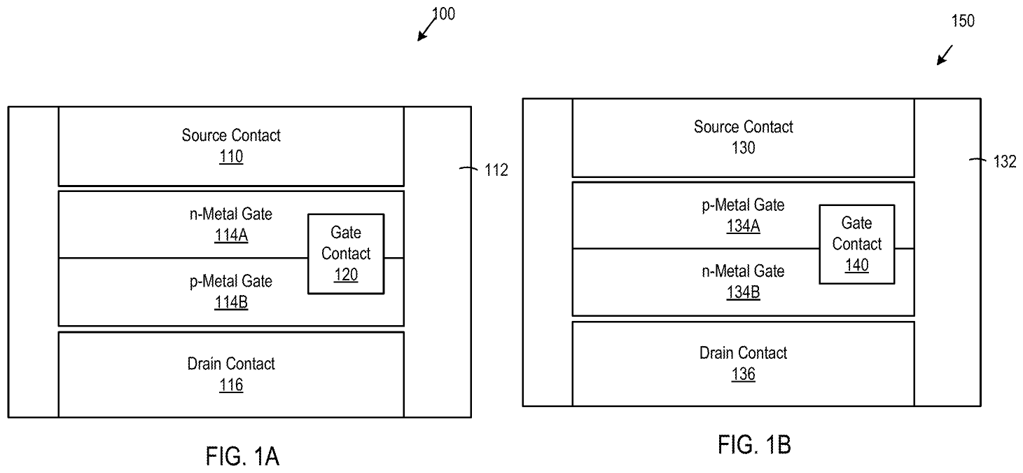

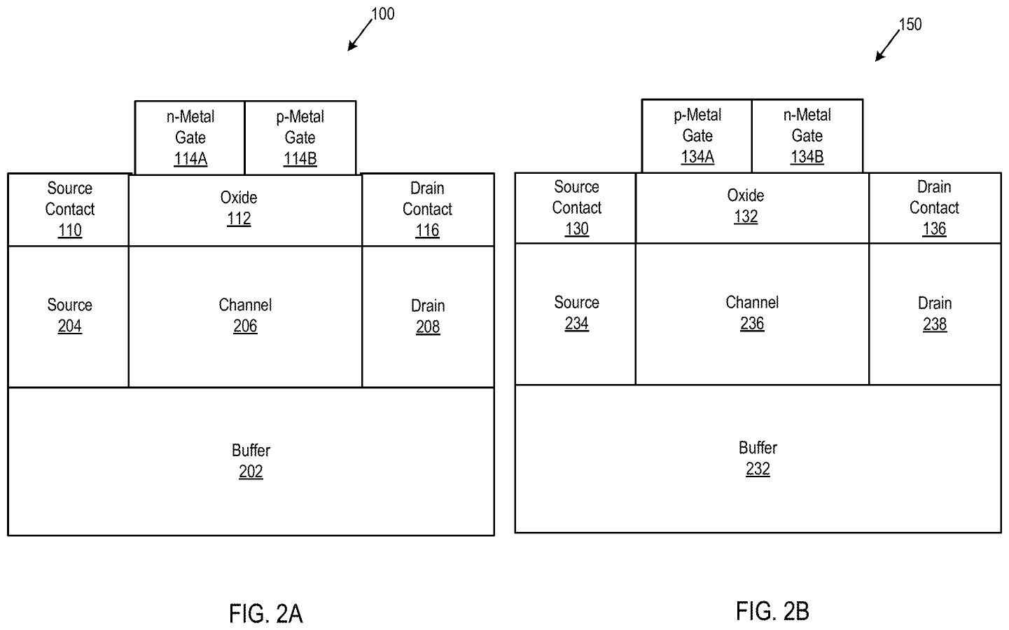

FIG. 1A illustrates a simplified planar view of an NMOS transistor 100 with dual gate workfunctions, according to some embodiments. The NMOS transistor 100 may comprise a source, drain, channel, and gate 114A, 114B (sometimes referred to together herein as “gate 114”). In this planar view a source contact 110, a gate 114, a gate contact 120, and a drain contact 116 are viewable. An oxide 112 (see FIG. 2A) may separate the gate 114 from the source contact 110 and the drain contact 116.

The NMOS transistor 100 can selectively allow current to flow between the source contact 110 and the drain contact 116. The gate 114 can control the conductivity of the channel to either restrict current flow or allow current to pass between the source contact 110 and the drain contact 116. When the NMOS transistor 100 is in an off-state, the current flow is restricted, whereas when the NMOS transistor 100 is in an on-state, the current is allowed to flow. The state of the NMOS transistor 100 is based on a voltage applied to the gate contact 120. For example, a high voltage on the gate contact 120 may cause the NMOS transistor 100 to be in an on-state, whereas a low voltage on the gate contact 120 may cause the NMOS transistor 100 to be in an off-state.

Thin film transistors can suffer low drive current due to insufficient injection current. For example, in a low-power device, the current at the source may be so small that a thermionic barrier may prevent many of the carriers at the source from being injected into the channel. This may result in low current for any component coupled to the drain.

The NMOS transistor 100 with dual gate workfunctions improves the injection current when compared to a transistor with a single gate workfunction. The increase in injection current provides an increase in the drive current. The dual gate workfunctions can reduce the source barrier for increased on-state current without impacting the off-state leakage. The additional drive current may improve device performance. For example, the additional drive current may help boost the speed in eDRAM products made of thin film transistors.

As shown, the gate 114 may comprise a first portion 114A with a first workfunction near the source contact 110 and a second portion 114B with a second workfunction near the drain contact 116. The gate 114 may transition between workfunctions along the channel direction from the source to the drain.

The first workfunction is different than the second workfunction. In some embodiments, the gate 114 is made of two metals with different workfunctions. For instance, as illustrated in FIG. 1A, the first portion 114A may comprise an n-type metal, and the second portion 114B may comprise a p-type metal for an n-type transistor (NMOS). The workfunctions are selected to reduce the thermionic barrier during a transistor on-state while maintaining the thermionic barrier during a transistor off-state.

FIG. 1B illustrates a simplified planar view of a PMOS transistor 150 with dual gate workfunctions, according to some embodiments. Similar to the NMOS transistor 100 of FIG. 1A, the PMOS transistor 150 may comprise a source, drain, channel, and gate 134A, 134B (sometimes referred to together as “gate 134”). In this planar view a source contact 130, a gate 134, a gate contact 140, and a drain contact 136 are viewable. An oxide 132 (FIG. 2B) may separate the gate 134 from the source contact 130 and the drain contact 136.

For the PMOS transistor 150, the workfunctions of the gate 124 are in reverse order relative to the gate 114 of the NMOS transistor 100 of FIG. 1A. As illustrated, the first portion 134A may comprise a p-type metal, and the second portion 134B may comprise an n-type metal for an p-type transistor (PMOS). The workfunctions are selected to reduce the thermionic barrier during a transistor on-state while maintaining the thermionic barrier during a transistor off-state.

FIG. 2A illustrates a simplified cross-sectional view taken through the gate 114 of the NMOS transistor 100 with dual gate workfunctions of FIG. 1A. As shown, the NMOS transistor 100 may be formed on a buffer 202.

As shown, a channel 206 may be formed (e.g., deposited) on the buffer. The channel 206 may include a metallic oxide semiconductor material. A source region 204 and a drain region 208 may be formed at either end of the channel 206. In some embodiments, the NMOS transistor 100 may comprise a channel 206, source region 204, and drain region 208 comprising one material. For example, the channel 206, source region 204, and drain region 208 may include a metal oxide or a transparent metal. The material may be naturally n-type due to oxygen vacancies in the channel material.

In some embodiments, the source region 204 and drain region 208 may be doped to form a p-type transistor or an n-type transistor. For example, a p-type transistor may include a source region 204 and a drain region 208 that have been doped with one or more p-type dopants. A source contact 110 and a drain contact 116 may be formed on the source region 204 and the drain region 208, respectively, to facilitate current conduction. The oxide 112 may be deposited to prevent shorting between the gate 114, source contact 110, and drain contact 116 and the channel 206.

The gate 114 may include two different portions 114A, 114B comprising two different metals. Each metal has a different workfunction. For example, in some embodiments, the first portion 114A is nearer the source region 204 and comprises a metal that corresponds to the dopant type of the source and drain regions 204, 208. Thus, the charge carrier of the source and drain regions 204, 208 may correspond with the workfunction of the first portion 114A. For example, in the illustrated embodiment, the first portion 114A is an n-type metal and the source region 204 and the drain region 208 are n-type. The second portion 1146 is a different work function than the first portion 114A. For example, if the first portion 114A is a n-type metal, the second portion 114B may comprise a p-type metal. Due to the non-symmetric gate, the source region and the drain region are not interchangeable like a typical transistor. In some embodiments, a diode may limit the direction of current flow to ensure the NMOS transistor 100 is biased correctly.

The placement of the different metals can be adjusted based on the type of transistor. The metal that provides a lower thermionic barrier can be positioned closer to the source to lower the source barrier. In some embodiments, a p-type transistor with dual gate workfunctions has a p-type source and drain, and the gate includes a p-type metal near the source and an n-type metal near the drain. In some embodiments, an n-type transistor with dual gate workfunctions has a n-type source and drain, and the gate includes an n-type metal near the source and a p-type metal near the drain.

The dimensions of the first portion 114A and the second portion 114B may be adjusted to generate a target thermionic barrier. In the illustrated embodiment, the first portion 114A is equal in length (e.g., distance along the channel between the source region 204 and the drain region 208) to the second portion 1146. In other embodiments, the first portion 114A may be longer or shorter than the second portion 1146. A longer first portion 114A may lower the on-state thermionic barrier but may also lower the off-state thermionic barrier or allow tunneling current. A shorter first portion 114A may increase the on-state thermionic barrier and increase the off-state thermionic barrier and reduce tunneling current. Thus, the length of the first portion 114A and the second portion 114B may be scaled to adjust the on-state and off-state conduction band energy.

FIG. 2B illustrates a cross-sectional view taken through the gate 134 of the PMOS transistor 150 with dual gate workfunctions of FIG. 1B. As shown, the PMOS transistor 150 may be formed on a buffer 232 and have the similar features of the NMOS transistor 100 of FIG. 2A including a source contact 130, a source 234, a channel 236, a drain, 238 and a drain contact 136. However, the source 234 and drain 358 may be p-type, and the workfunctions of the gate portions 134A and 134B are reversed. Thus, in a PMOS transistor 150 to lower the thermionic barrier at the source, a first portion 134A of the gate nearer the source is a p-Metal and the second portion 134B of the gate nearer the drain is an n-Metal.

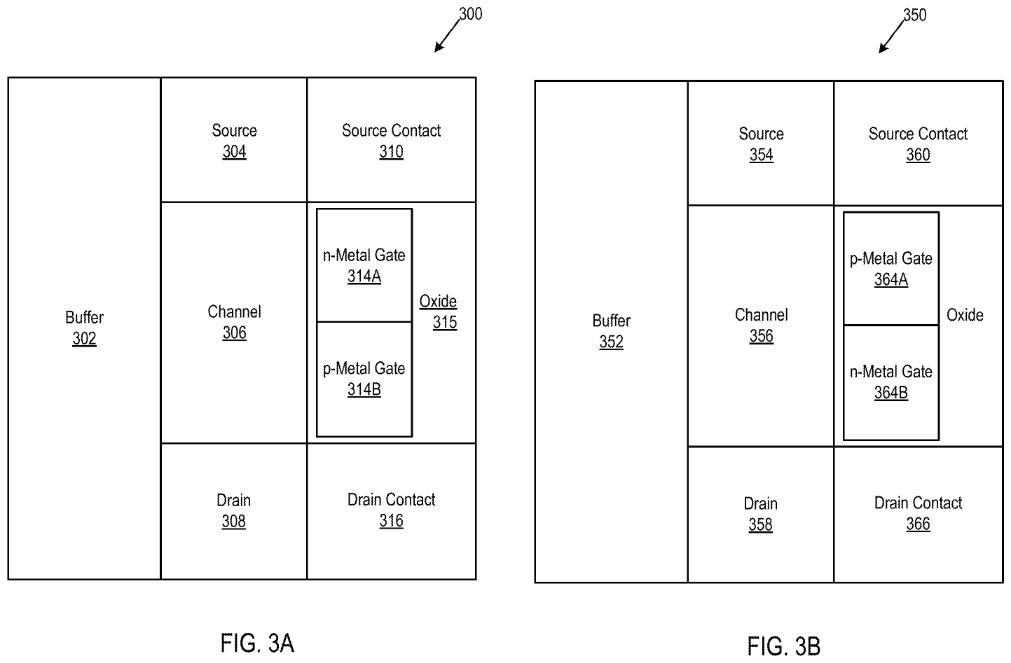

FIG. 3A illustrates a simplified cross-sectional view taken through a gate 314A, 314B (sometimes referred to herein together as “gate 314”) of a vertical thin film NMOS transistor 300 with dual gate workfunctions, according to some embodiments. The gate 314 comprises a first portion 314A and a second portion 314B along the channel direction from a source region 304 to a drain region 308. The PMOS transistor includes a buffer 302, a source 304, a drain 308, a channel 306, an n-Metal Gate 314A, a p-Metal gate 314B an oxide 315, a source contact 310, and a drain contact similar to the buffer 202, the source 204, the drain 208, the channel 206, n-Metal Gate 114A, the p-Metal gate 114B, the oxide 112, thea source contact 110, and the drain contact 116 of the n-MOS transistor 100 of FIGS. 1A and 2A.

While FIG. 3A illustrates a vertical thin film NMOS transistor 300 with dual gate workfunctions, any details described in reference to the planar NMOS transistor 100 of FIGS. 1 and 2 may be applied to the NMOS transistor 300 of FIG. 3A. For example, the first portion 314A may lower the on-state thermionic barrier of the vertical thin film NMOS transistor 300, facilitating a higher drive current than a single workfunction gate. And the second portion 314B may provide a sufficiently high thermionic barrier during the off-state that little to no leakage current is allowed along the channel 306. The vertical thin film NMOS transistor 300 with dual gate workfunctions demonstrates that the dual gate workfunctions may be applied to a variety of transistor architectures and geometries.

Drive current is particularly limited with thin film transistors. Thin film transistors typically suffer from low drive current. This is at least partially due to low carrier mobility of a thin film transistor. This makes thin film transistors good for power conservation during an off state, but difficult to change to an on state. Materials used for thin film transistor channels often have low mobility that limits the carrier conduction. For example, some channels comprise non-silicon material such as metal oxide or transparent metal. Because of the low drive current thin film transistors have conventionally been limited to displays. However, a thin film transistor with a multi-workfunction gate may be configured to be used as a standard transistor. A multi-workfunction gate as described herein can be applied to a thin film transistor to increase the drive current by reducing the thermionic barrier during an on state. Further, the off state thermionic barrier may be preserved.

Typically, a thin film transistor is n-type due to the materials used in the device. In the illustrated embodiment, the vertical thin film NMOS transistor 300 comprises a source, channel, and drain formed from an n-type material such as metal oxide. Thus, to lower the thermionic barrier, the first portion 314A of the gate comprises a n-type metal corresponding to the n-type material forming the source, channel, and drain. The second portion 314B of the gate comprises a p-type metal to maintain the thermionic barrier during an off-state of the vertical thin film NMOS transistor 300. Due to the non-symmetric gate, the source region and the drain region are not interchangeable like a typical transistor. In some embodiments, a diode may limit the direction of current flow to ensure the vertical thin film NMOS transistor 300 is biased correctly.

The vertical structure may reduce the footprint of a thin film transistor and facilitate manufacturing. For example, the channel 306 may be longer than a width of the drain region 308 and drain contact 316. In such a case the vertical thin film transistor 300 would extend vertically from a board further than the vertical thin film transistor 300 extends along the board, thereby conserving board space.

Additionally manufacturing may be done using standard processing such as vertical deposition. For example, the drain region 308 and the drain contact 316 may be deposited. Then the channel, the second portion 314B and first portion 314A of the gate deposited on top of the drain region 308 and drain contact 316. The source region 304 and the source contact 310 may be deposited on top of the gate and channel 306.

FIG. 3B illustrates a simplified cross-sectional view taken through the gate of a vertical thin film PMOS transistor 350 with dual gate workfunctions, according to some embodiments. As shown, the vertical thin film PMOS transistor 350 include similar features of the vertical thin film NMOS transistor 300 of FIG. 3A including a source contact 360, a source 354, a channel 356, a drain, 358 and a drain contact 366, similar to the source contact 130, the source 234, the channel 236, the drain 238, and the drain contact 136 of FIGS. 1B and 2B. However, the source 234 and drain 358 may be p-type, and the workfunctions of the gate portions 364A and 364B are reversed. Thus, in a vertical thin film PMOS transistor 350 to lower the thermionic barrier at the source, a first portion 364A of the gate nearer the source 354 is a p-Metal and the second portion 364B of the gate nearer the drain 358 is an n-Metal.

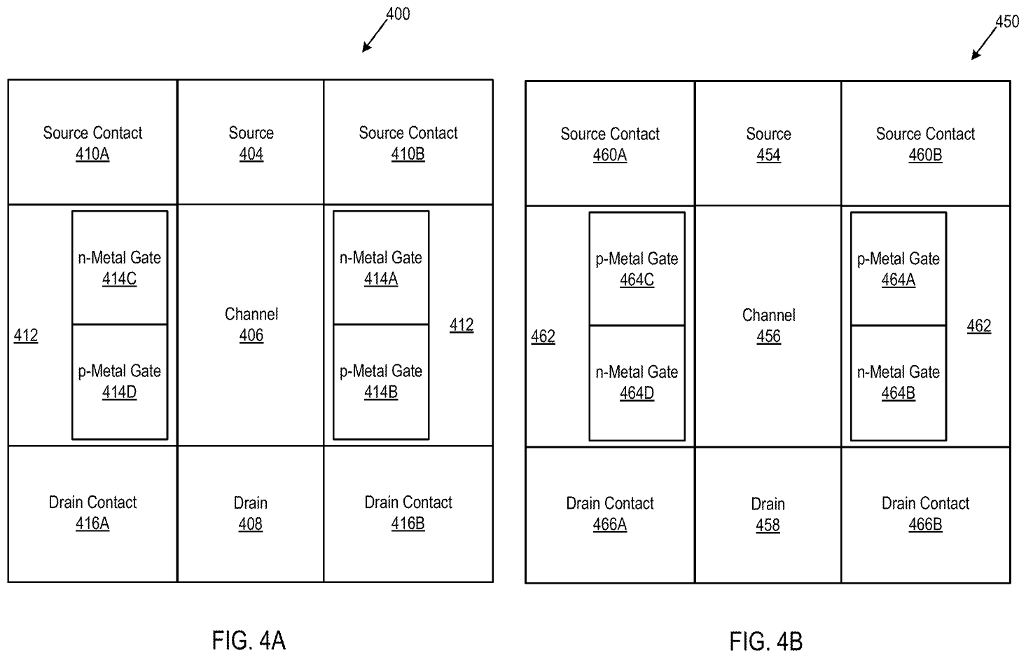

FIG. 4A illustrates a simplified cross-sectional view of a double gate transistor 400 with dual gate workfunctions, according to some embodiments. Just as is described with reference to FIGS. 1-3, each gate 414A-B and 414C-D comprises two portions with two different workfunctions. The first portions 414A, 414C are located near the source 404 and are a metal with a workfunction corresponding to the source 404. For instance, as shown the source 404 is n-type and the first portions 414A, 414C are n-type metals. The second portions 414D, 414B are nearer the drain 408 and are a metal with a workfunction that is more p-type than the first portions 414A, 414C. An oxide 412 separates the gates 414 from the source contacts 410A, 410B, the channel 406, and the drain contacts 416A, 416B.

FIG. 4B illustrates a simplified cross-sectional view of a vertical double gate PMOS transistor 450 with dual gate workfunctions, according to some embodiments. each gate 464A-B and 464C-D comprises two portions with two different workfunctions. The first portions 464A, 464C are located near the source 454 and are a metal with a workfunction corresponding to the source 454. For instance, as shown the source 454 is p-type and the first portions 464A, 464C are p-type metals. The second portions 464D, 464B are nearer the drain 458 and are a metal with a workfunction that is more n-type than the first portions 464A, 464C. An oxide 462 separates the gates 464 from the source contacts 460A, 460B, the channel 456, and the drain contacts 466A, 466B.

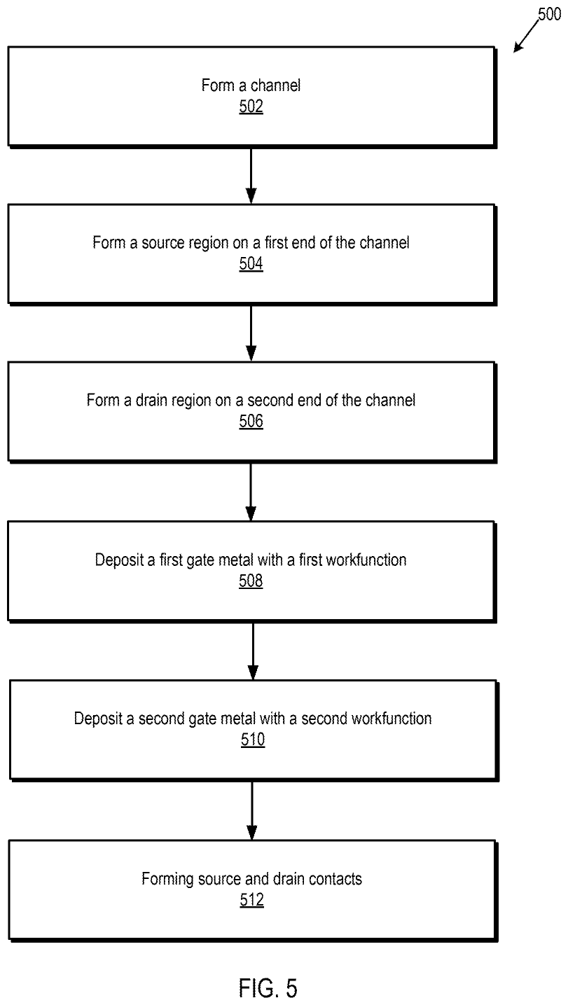

FIG. 5 is a flow diagram illustrating a method 500 for fabricating a transistor with dual gate workfunctions, according to some embodiments. The method 500 includes forming 502 a channel comprising a semiconductor doped with a first type of dopant. The channel may be formed using standard processing techniques. For example, the fins can be formed using etching, photolithography, and/or epitaxial growth.

The method 500 further includes forming 504 a source region on a first end of the channel, and forming 506 a drain region on a second end of the channel. The source region and the drain region may be doped with a second type of dopant. The source region and the drain region can be formed simultaneously with the same materials.

The method 500 may further include depositing 508, 510 a gate to control a conductivity of the channel. The gate may include a first portion with a first workfunction and a second portion with a second workfunction. The first workfunction can be different than the second workfunction. Further, one of the portions is nearer the source than the other portion. In some embodiments, the first workfunction results in a lower thermionic barrier than the second workfunction to lower the injection barrier of the channel.

For example, in some embodiments, the method 500 may include depositing 508 a first metal with a first workfunction to form the first portion, and depositing 510 a second metal to form the second portion. In some embodiments, these metals are different from each other. The metal type of the portion nearer the source corresponds to the dopant of the source and drain. In some embodiments, the metal type of the first portion corresponds to the type of the transistor. For example, for an n-type transistor, the first portion may comprise an n-type metal and the second portion may comprise a p-type metal. For a p-type transistor, the first portion may comprise a p-type metal and the second portion may comprise an n-type metal.

The method may further include forming 512 source and drain contacts. The source and drain contacts may include an annealed contact. For example, the drain region may include a first ohmic contact and the source region may include a second ohmic contact. The source and the drain contacts should be biased to cause current to travel between the source region and the drain region. If the transistor is biased in reverse, the source thermionic barrier may not be lowered.

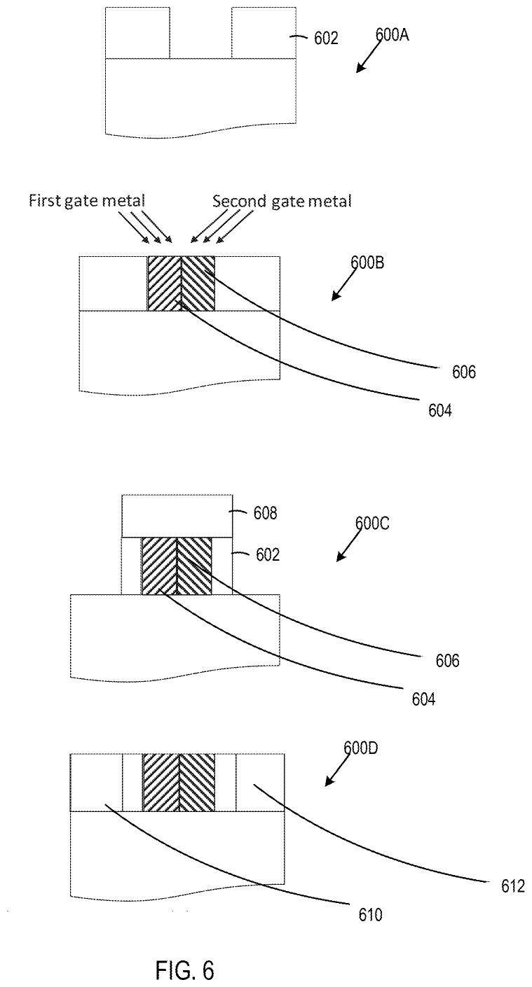

FIG. 6 illustrates simplified cross-sectional views of a transistor 600A-600D (sometimes referred to generically herein as “transistor 600”) taken through the gate of the transistor 600, the transistor 600 including a gate with dual gate workfunctions. These cross-sectional views are taken during various processing acts according to a first embodiment. The transistor 600A has an oxide layer 602 partially removed. A first gate metal 604 and a second gate metal 606 are deposited on the transistor 600B. In some embodiments, an angled deposition is used to deposit both metals at the same time. The oxide layer 602 of the transistor 600C may be etched to open an area for the source and drain regions. A sacrificial layer 608 may be deposited on the gate metals 604, 606. The source and the drain contacts 610, 612 are deposited on the transistor 600D and the sacrificial layer 608 is removed.

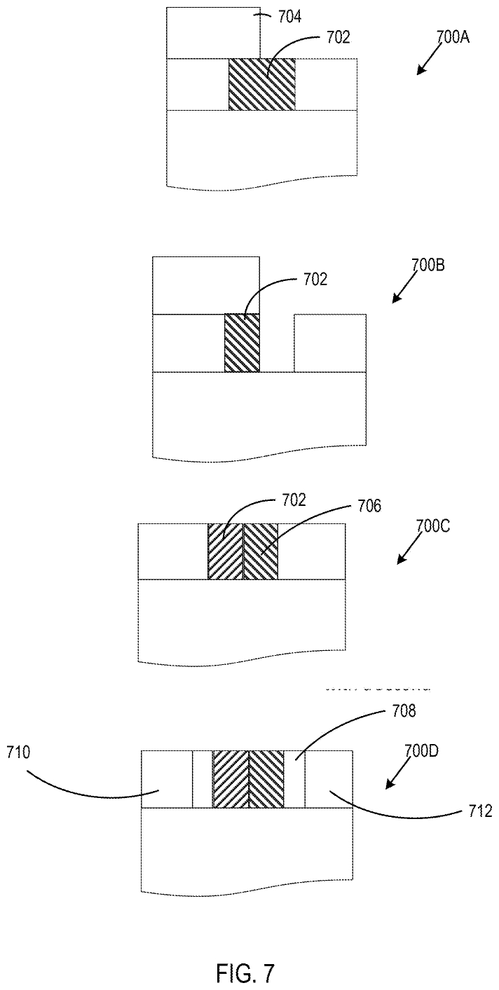

FIG. 7 illustrates a simplified cross-sectional view taken through the gate of a transistor 700A-700D (sometimes referred to generically herein as “transistor 700”) with dual gate workfunctions during various processing stages according to some embodiments. A first gate metal 702 with a first workfunction is deposited on a transistor 700A, and resist 704 is deposited over a portion of the first gate metal 702. A portion of the first gate metal 702 not covered by the resist 704 is removed from the transistor 700B. A second gate metal 706 with a second workfunction is deposited where the first gate metal 702 was removed on the transistor 700C. The transistor 700D has portions of oxide 708 removed and a source contact 710 and a drain contact 712 are deposited.

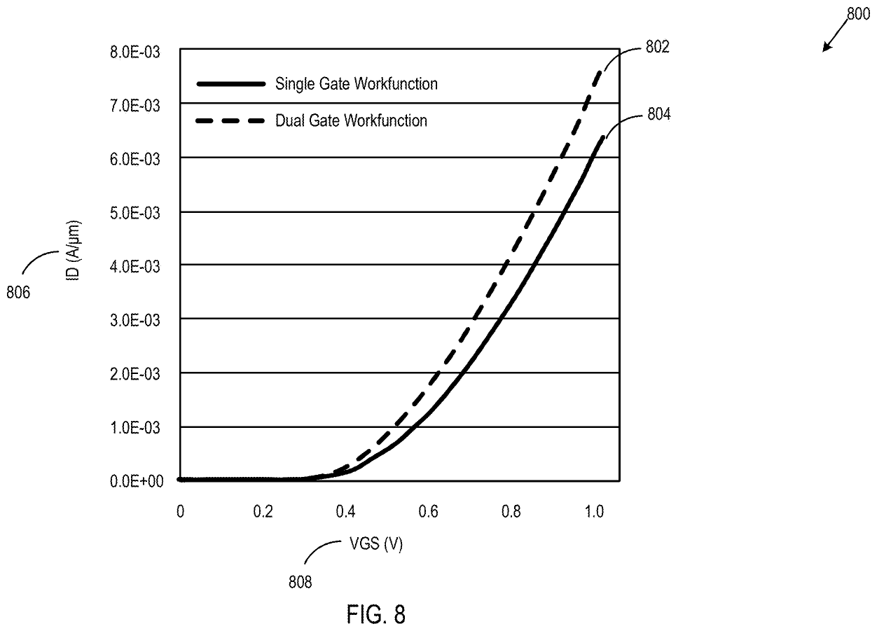

FIG. 8 is a simplified graph 800 comparing on-state current of a transistor with dual gate workfunctions 802 with a transistor with a single gate workfunction 804. The graph 800 compares drive current 806 as a function of gate voltage 808. In this comparison, the dual gate workfunction transistor 802 and the transistor with a single gate workfunction 804 have a matched off-state leakage at VGS=0V. As illustrated, the dual gate workfunctions 802 can provide about a 20% drive current improvement over a transistor with a single gate workfunction 804 at VGS=1V.

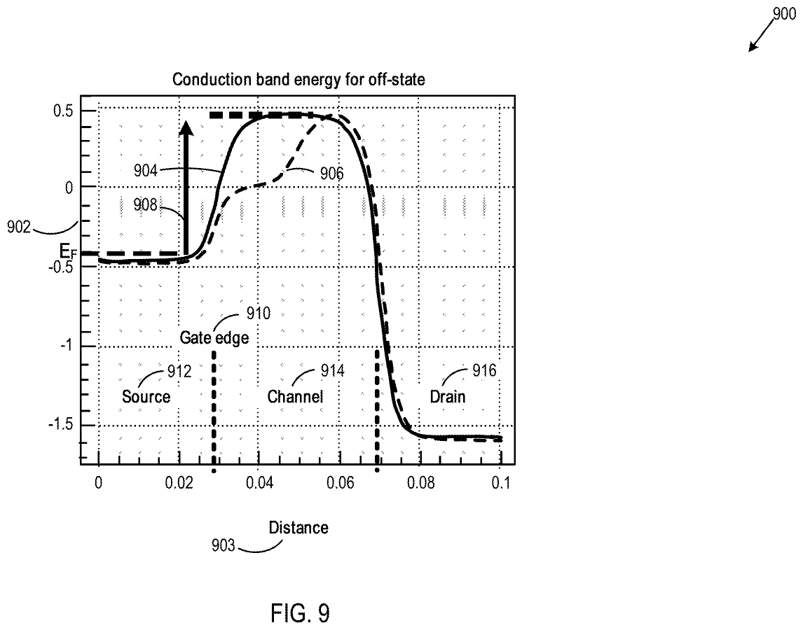

FIG. 9 is a simplified graph 900 comparing off-state conduction band energy 906 of a transistor with dual gate workfunctions with off-state conduction band energy 904 of a transistor with a single gate workfunction. The graph 900 compares conduction band energy 902 across a distance 903 of the transistor. For reference, the graph 900 depicts features of the transistor including the source 912, the gate edge 910, the channel 914, and the drain 916.

As shown by the off-state conduction band energy 906, the thermionic barrier height 908 is the same for the transistor with dual gate workfunctions as the off-state conduction band energy 904 for the transistor with a single gate workfunction. As shown, a first workfunction of the gate near the source 912 may lower the thermionic barrier height 908 across a first portion of the channel 914. However, the second workfunction of the gate provides a thermionic barrier height 908 equivalent to that corresponding to the single gate workfunction. Thus, both the transistor with dual gate workfunctions and the transistor with a single gate workfunction give similar off-state leakage.

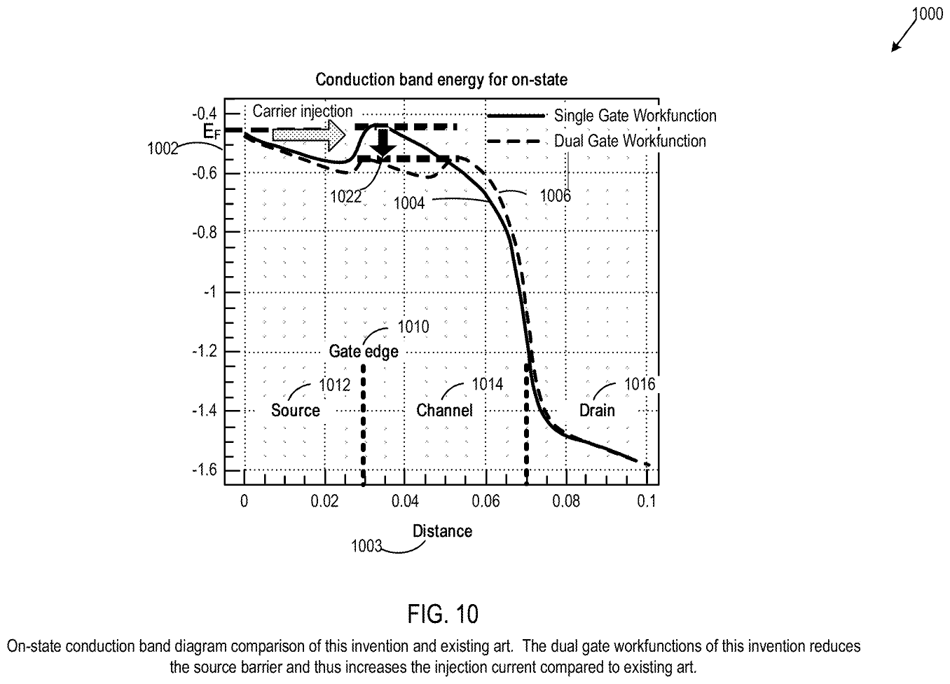

FIG. 10 is a simplified graph 1000 comparing on-state conduction band energy 1006 of a transistor with dual gate workfunctions to on-state conduction band energy 1004 of a transistor with a single gate workfunction. The graph 1000 compares conduction band energy 1002 across a distance 1003 of the transistors. For reference, the graph 1000 depicts features of the transistor including the source 1012, the gate edge 1010, the channel 1014, and the drain 1016.

As shown, the transistor with dual gate workfunctions (corresponding to the on-state conduction band energy 1006) has a lower source barrier 1022 than the transistor with a single gate workfunction (corresponding to the on-state conduction band energy 1004). The source barrier of a transistor limits the injection current, thereby limiting the drive current. A lower source barrier will result in a larger injection current and drive current. Thus, the lower source barrier 1022 results in a larger injection current for the on-state for the transistor with dual gate workfunctions when compared with the transistor with a single gate workfunction, without compromising on off-state leakage current (as discussed above with reference to FIG. 9).

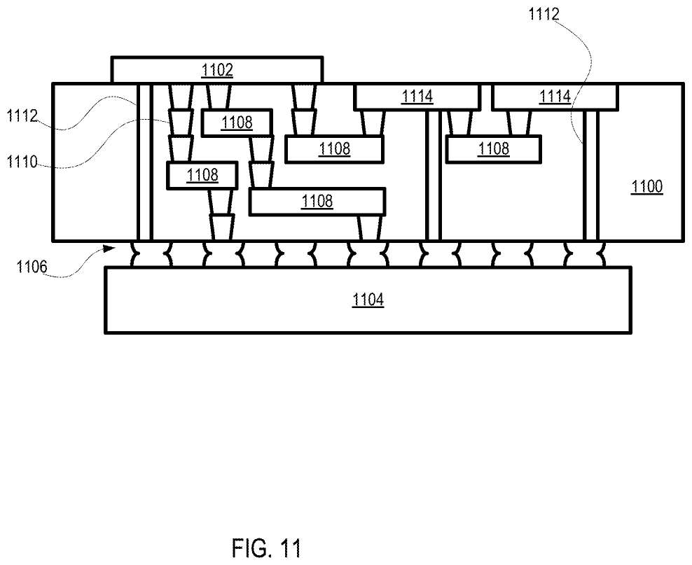

FIG. 11 illustrates an interposer 1100 that includes one or more embodiments of the disclosure. The interposer 1100 is an intervening substrate used to bridge a first substrate 1102 to a second substrate 1104. The first substrate 1102 may be, for instance, an integrated circuit die. The second substrate 1104 may be, for instance, a memory module, a computer motherboard, or another integrated circuit die. Generally, the purpose of an interposer 1100 is to spread a connection to a wider pitch or to reroute a connection to a different connection. For example, an interposer 1100 may couple an integrated circuit die to a ball grid array (BGA) 1106 that can subsequently be coupled to the second substrate 1104. In some embodiments, the first and second substrates 1102, 1104 are attached to opposing sides of the interposer 1100. In other embodiments, the first and second substrates 1102, 1104 are attached to the same side of the interposer 1100. And in further embodiments, three or more substrates are interconnected by way of the interposer 1100.

The interposer 1100 may be formed of an epoxy resin, a fiberglass-reinforced epoxy resin, a ceramic material, or a polymer material such as polyimide. In further implementations, the interposer may be formed of alternative rigid or flexible materials that may include the same materials described above for use in a semiconductor substrate, such as silicon, germanium, and other group III-V and group IV materials.

The interposer may include metal interconnects 1108 and vias 1110, including but not limited to through-silicon vias (TSVs) 1112. The interposer 1100 may further include embedded devices 1114, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1100.

In accordance with embodiments of the disclosure, apparatuses or processes disclosed herein may be used in the fabrication of interposer 1100. By way of non-limiting example, the first substrate 1102, the second substrate 1104, the interposer 1100, or combinations thereof may include one or more of the transistors 100, 150, 300, 350, 400, 450, 600, 700 discussed above with reference to FIGS. 1A, 1B, 2A, 2B, 3A, 3B, 4A, 4B, 6, and 7.

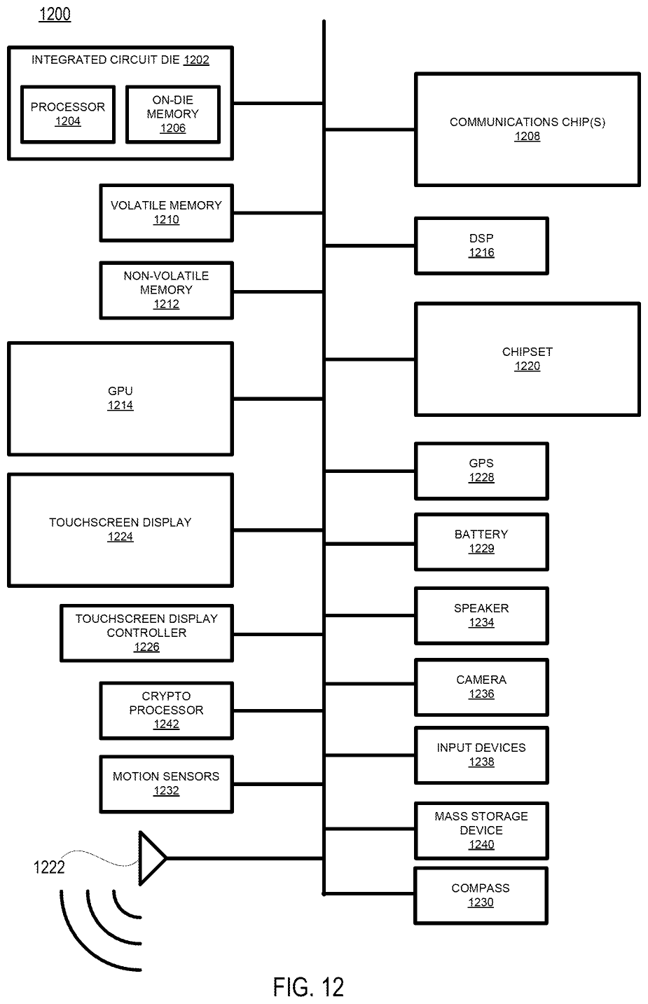

FIG. 12 illustrates a computing device 1200 in accordance with one embodiment of the disclosure. The computing device 1200 may include a number of components. In one embodiment, these components are attached to one or more motherboards. In an alternative embodiment, some or all of these components are fabricated onto a single system-on-a-chip (SoC) die, such as an SoC used for mobile devices. The components in the computing device 1200 include, but are not limited to, an integrated circuit die 1202 and at least one communications chip 1208 (e.g., a communications logic unit). In some implementations the communications chip 1208 is fabricated within the integrated circuit die 1202 while in other implementations the communications chip 1208 is fabricated in a separate integrated circuit chip that may be bonded to a substrate or motherboard that is shared with or electronically coupled to the integrated circuit die 1202. The integrated circuit die 1202 may include a processor 1204 (e.g., a CPU) as well as on-die memory 1206, often used as cache memory, which can be provided by technologies such as embedded DRAM (eDRAM), SRAM, or spin-transfer torque memory (STT-MRAM).

Computing device 1200 may include other components that may or may not be physically and electrically coupled to the motherboard or fabricated within an SoC die. These other components include, but are not limited to, volatile memory 1210 (e.g., DRAM), non-volatile memory 1212 (e.g., ROM or flash memory), a graphics processing unit (GPU) 1214, a digital signal processor (DSP) 1216, a crypto processor 1242 (e.g., a specialized processor that executes cryptographic algorithms within hardware), a chipset 1220, at least one antenna 1222 (in some implementations two or more antennae may be used), a display or a touchscreen display 1224, a touchscreen display controller 1226, a battery 1229 or other power source (not shown), a power amplifier (not shown), a voltage regulator (not shown), a global positioning system (GPS) device 1228, a compass 1230, one or more motion sensors 1232 (e.g., a motion coprocessor such as an accelerometer, a gyroscope, a compass, etc.), a microphone (not shown), a speaker 1234, a camera 1236, user input devices 1238 (such as a keyboard, mouse, stylus, and touchpad), and a mass storage device 1240 (such as a hard disk drive, compact disk (CD), digital versatile disk (DVD), and so forth). The computing device 1200 may incorporate further transmission, telecommunication, or radio functionality not already described herein. In some implementations, the computing device 1200 includes a radio that is used to communicate over a distance by modulating and radiating electromagnetic waves in air or space. In further implementations, the computing device 1200 includes a transmitter and a receiver (or a transceiver) that is used to communicate over a distance by modulating and radiating electromagnetic waves in air or space.

The communications chip 1208 may include a communications logic unit configured to transfer data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications chip 1208 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, and derivatives thereof, as well as any other wireless protocols that are designated as 3G, 4G, 5G, and beyond. The computing device 1200 may include a plurality of communications chips 1208. For instance, a first communications chip 1208 may be dedicated to shorter range wireless communications such as Wi-Fi, NFC, and Bluetooth and a second communications chip 1208 may be dedicated to longer range wireless communications such as GPS, EDGE, GPRS, CDMA, WiMAX, LTE, Ev-DO, and others.

The processor 1204 of the computing device 1200 includes one or more devices, such as transistors with dual gate workfunctions, that are formed in accordance with embodiments of the disclosure. The term “processor” may refer to any device or portion of a device that processes electronic data from registers and/or memory to transform that electronic data into other electronic data that may be stored in registers and/or memory.

The communications chip 1208 may also include one or more devices, such as transistors with dual gate workfunctions, that are formed in accordance with embodiments of the disclosure.

In further embodiments, another component housed within the computing device 1200 may contain one or more devices, such as transistors with dual gate workfunctions, that are formed in accordance with implementations of the disclosure.

In various embodiments, the computing device 1200 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1200 may be any other electronic device that processes data.

### EXAMPLES

The following is a list of example embodiments that fall within the scope of the disclosure. In order to avoid complexity in providing the disclosure, not all of the examples listed below are separately and explicitly disclosed as having been contemplated herein as combinable with all of the other examples listed below and other embodiments disclosed hereinabove. Unless one of ordinary skill in the art would understand that these examples listed below, and the above disclosed embodiments, are not combinable, it is contemplated within the scope of the disclosure that such examples and embodiments are combinable.

Example 1 is a transistor comprising: a source region comprising a semiconductor material; a drain region comprising a semiconductor material; a channel between the source region and the drain region; and a gate to control a conductivity of the channel, the gate comprising: a first portion with a first workfunction corresponding to charge majority carriers of the semiconductor material of the source, and a second portion with a second workfunction, wherein the first workfunction is different than the second workfunction, wherein the first portion is over a first segment of the channel, and the second portion is over a second segment of the channel, wherein the first segment of the channel is nearer the source than the second segment of the channel.

Example 2 is the transistor of Example 1, wherein the first portion is a first metal and the second portion is a second metal, wherein the first metal is different than the second metal.

Example 3 is the transistor of Example 2, wherein the source is an n-type semiconductor, the first metal is an n-type metal, and the second metal is a p-type metal.

Example 4 is the transistor of Example 2, wherein the source is a p-type semiconductor, the first metal is a p-type metal, and the second metal is an n-type metal.

Example 5 is the transistor according to any one of Examples 1-4, wherein the first portion and the second portion have the same dimensions.

Example 6 is the transistor according to any one of Examples 1-4, wherein the transistor is a thin film transistor.

Example 7 is the transistor of Example 6, wherein the source region, the drain region, and the channel comprises a metal oxide, or a transparent metal.

Example 8 is the transistor according to any one of Examples 1-4, wherein the first workfunction has a lower thermionic barrier than the second workfunction.

Example 9 is a method comprising: forming a channel comprising a semiconductor; forming a source region on a first end of the channel; forming a drain region on a second end of the channel; and forming a gate to control a conductivity of the channel, the gate comprising: a first portion with a first workfunction proximate the source region, and a second portion with a second workfunction proximate the drain region, wherein the first workfunction has a lower thermionic source barrier than the second workfunction.

Example 10 is the method of Example 9, wherein depositing the gate comprises depositing a first metal to form the first portion, and depositing a second metal to form the second portion, wherein the first metal is different than the second metal.

Example 11 is the method of Example 10, wherein the charge majority carriers are holes, the first metal is a p-type metal, and the second metal is an n-type metal.

Example 12 is the method of Example 10, wherein the charge majority carriers are electrons, the first metal is an n-type metal the second metal is a p-type metal.

Example 13 is the method of Example 9, wherein the first workfunction has a lower thermionic barrier than the second workfunction.

Example 14 is the method of Example 9, wherein the source region, the drain region, and the channel comprises a metal oxide, or a transparent metal.

Example 15 is a computing device comprising one or more transistors, each of the one or more transistors comprising: a source region comprising a semiconductor material; a drain region comprising a semiconductor material; a channel between the source region and the drain region; and a gate to control a conductivity of the channel, the gate comprising: a first portion with a first workfunction corresponding to charge majority carriers of the semiconductor material of the source, and a second portion with a second workfunction, wherein the first workfunction is different than the second workfunction, wherein the first portion is over a first segment of the channel, and the second portion is over a second segment of the channel, wherein the first segment of the channel is nearer the source than the second segment of the channel.

Example 16 is the computing device of Example 15, further comprising: a processor mounted on the substrate; a memory unit capable of storing data; a graphics processing unit; an antenna within the computing device; a display on the computing device; a battery within the computing device; a power amplifier within the processor; and a voltage regulator within the processor; wherein at least one of the processor, the memory unit, the graphics processing unit, or the voltage regulator comprises the one or more transistors.

Example 17 is the computing device of Example 15, wherein the first portion is a first metal and the second portion is a second metal, wherein the first metal is different than the second metal.

Example 18 is the computing device of Example 17, wherein the transistor is a thin film transistor.

Example 19 is the computing device of Example 18, wherein the source region, the drain region, and the channel comprises a metal oxide, or a transparent metal.

Example 20 is the computing device according to any one of Examples 15-19, wherein the first workfunction has a lower thermionic barrier than the second workfunction.

Example 21 is a method of manufacturing a transistor comprising: forming a source region comprising a semiconductor material; forming a drain region comprising a semiconductor material; forming a channel between the source region and the drain region; and forming a gate to control a conductivity of the channel, the gate comprising: a first portion with a first workfunction corresponding to charge majority carriers of the semiconductor material of the source, and a second portion with a second workfunction, wherein the first workfunction is different than the second workfunction, wherein the first portion is over a first segment of the channel, and the second portion is over a second segment of the channel, wherein the first segment of the channel is nearer the source than the second segment of the channel.

Example 22 is the method of manufacturing a transistor of Example 21, wherein the first portion is a first metal and the second portion is a second metal, wherein the first metal is different than the second metal.

Example 23 is the method of manufacturing a transistor of Example 22, wherein the source is an n-type semiconductor, the first metal is an n-type metal, and the second metal is a p-type metal.

Example 24 is the method of manufacturing a transistor of Example 22, wherein the source is a p-type semiconductor, the first metal is a p-type metal, and the second metal is an n-type metal.

Example 25 is the method of manufacturing a transistor of Example 21, wherein the first portion and the second portion have the same dimensions.

Example 26 is the method of manufacturing a transistor of Example 21, wherein the transistor is a thin film transistor.

Example 27 is the method of manufacturing a transistor of Example 26, wherein the source region, the drain region, and the channel comprises a metal oxide, or a transparent metal.

Example 28 is the method of manufacturing a transistor of Example 21, wherein the first workfunction has a lower thermionic barrier than the second workfunction.

Example 29 is an apparatus comprising: a channel comprising a semiconductor; a source region on a first end of the channel; a drain region on a second end of the channel; and a gate to control a conductivity of the channel, the gate comprising: a first portion with a first workfunction proximate the source region, and a second portion with a second workfunction proximate the drain region, wherein the first workfunction has a lower thermionic source barrier than the second workfunction.

Example 30 is the apparatus of Example 29, wherein the gate comprises a first metal to form the first portion, and a second metal to form the second portion, wherein the first metal is different than the second metal.

Example 31 is the apparatus of Example 30, wherein the charge majority carriers are holes, the first metal is a p-type metal, and the second metal is an n-type metal.

Example 32 is the apparatus of Example 30, wherein the charge majority carriers are electrons, the first metal is an n-type metal the second metal is a p-type metal.

Example 33 is the apparatus according to any one of Examples 29-32, wherein the first workfunction has a lower thermionic barrier than the second workfunction.

Example 34 is the apparatus according to any one of Examples 29-32, wherein the source region, the drain region, and the channel comprises a metal oxide, or a transparent metal.

Example 35 is a method of operating a computing device comprising one or more transistors, the method comprising: applying a source voltage potential a source potential to a source region; and selectively applying a gate voltage potential to an electrically conductive material to control a conductivity of the channel, the gate comprising: a first portion with a first workfunction corresponding to charge majority carriers of the semiconductor material of the source, and a second portion with a second workfunction, wherein the first workfunction is different than the second workfunction, wherein the first portion is over a first segment of the channel, and the second portion is over a second segment of the channel, wherein the first segment of the channel is nearer the source than the second segment of the channel.

Example 36 is the method of Example 35, wherein the first portion is a first metal and the second portion is a second metal, wherein the first metal is different than the second metal.

Example 37 is the method of Example 36, wherein the transistor is a thin film transistor.

Example 38 is the method of Example 37, wherein the source region, the drain region, and the channel comprises a metal oxide, or a transparent metal.

Example 39 is the method of Example 35, wherein the first workfunction has a lower thermionic barrier than the second workfunction.

Example 40 is a means for performing at least a portion of the method according to any one of Examples 9-14, 21-28, and 35-39.

Example 41 is a computer-readable storage medium comprising computer-readable instructions stored thereon, the computer-readable instructions configured to instruct a processor to perform at least a portion of the method according to any one of Examples 9-14, 21-28, and 35-39.

It will be obvious to those having skill in the art that many changes may be made to the details of the above-described embodiments without departing from the underlying principles of the invention. The scope of the present invention should, therefore, be determined only by the following claims.

1. A transistor comprising:
a source region comprising a semiconductor material;
a drain region comprising a semiconductor material;
a channel between the source region and the drain region; and
a gate to control a conductivity of the channel, the gate comprising:
a first portion with a first workfunction corresponding to charge majority carriers of the semiconductor material of the source, and
a second portion with a second workfunction, wherein the first workfunction is different than the second workfunction, wherein the first portion is over a first segment of the channel, and the second portion is over a second segment of the channel, wherein the first segment of the channel is nearer the source than the second segment of the channel.

2. The transistor of claim 1, wherein the first portion is a first metal and the second portion is a second metal, wherein the first metal is different than the second metal.

3. The transistor of claim 1, wherein the source is an n-type semiconductor, the first metal is an n-type metal, and the second metal is a p-type metal.

4. The transistor of claim 1, wherein the source is a p-type semiconductor, the first metal is a p-type metal, and the second metal is an n-type metal.

5. The transistor of claim 1, wherein the first portion and the second portion have the same dimensions.

6. The transistor of claim 1, wherein the transistor is a thin film transistor.

7. The transistor of claim 6, wherein the source region, the drain region, and the channel comprises a metal oxide, or a transparent metal.

8. The transistor of claim 1, wherein the first workfunction has a lower thermionic barrier than the second workfunction.

9. A method comprising:
forming a channel comprising a semiconductor;
forming a source region on a first end of the channel;
forming a drain region on a second end of the channel; and
forming a gate to control a conductivity of the channel, the gate comprising:
a first portion with a first workfunction proximate the source region, and
a second portion with a second workfunction proximate the drain region, wherein the first workfunction has a lower thermionic source barrier than the second workfunction.

10. The method of claim 9, wherein depositing the gate comprises depositing a first metal to form the first portion, and depositing a second metal to form the second portion, wherein the first metal is different than the second metal.

11. The method of claim 9, wherein the charge majority carriers are holes, the first metal is a p-type metal, and the second metal is an n-type metal.

12. The method of claim 9, wherein the charge majority carriers are electrons, and the first metal is an n-type metal the second metal is a p-type metal.

13. The method of claim 9, wherein the first workfunction has a lower thermionic barrier than the second workfunction.

14. The method of claim 9, wherein the source region, the drain region, and the channel comprises a metal oxide, or a transparent metal.

15. A computing device comprising one or more transistors, each of the one or more transistors comprising:
a source region comprising a semiconductor material;
a drain region comprising a semiconductor material;
a channel between the source region and the drain region; and
a gate to control a conductivity of the channel, the gate comprising:
a first portion with a first workfunction corresponding to charge majority carriers of the semiconductor material of the source, and
a second portion with a second workfunction, wherein the first workfunction is different than the second workfunction, wherein the first portion is over a first segment of the channel, and the second portion is over a second segment of the channel, wherein the first segment of the channel is nearer the source than the second segment of the channel.

16. The computing device of claim 15, further comprising:
a processor mounted on the substrate;
a memory unit capable of storing data;
a graphics processing unit;
an antenna within the computing device;
a display on the computing device;
a battery within the computing device;
a power amplifier within the processor; and
a voltage regulator within the processor;
wherein at least one of the processor, the memory unit, the graphics processing unit, or the voltage regulator comprises the one or more transistors.

17. The computing device of claim 15, wherein the first portion is a first metal and the second portion is a second metal, wherein the first metal is different than the second metal.

18. The computing device of claim 15, wherein the transistor is a thin film transistor.

19. The computing device of claim 18, wherein the source region, the drain region, and the channel comprises a metal oxide, or a transparent metal.

20. The computing device of claim 15, wherein the first workfunction has a lower thermionic barrier than the second workfunction.
